(19) United States
(12) Patent Application Publication
(10) Pub. No.: US 2010/0155764 A1
(43) Pub. Date: Jun. 24, 2010

(54) GLASS-COVERED LIGHT-EMITTING ELEMENT AND GLASS-COVERED LIGHT-EMITTING DEVICE

(75) Inventors: Masayuki SERITA, Tokyo (JP); Nobuhiro Nakamura, Tokyo (JP); Syuji Matsumoto, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: ASAHI GLASS COMPANY, LIMITED, Tokyo (JP)

(21) Appl. No.: 12/717,204

(22) Filed: Mar. 4, 2010

Related U.S. Application Data
(63) Continuation of application No. PCT/JP2008/066191, filed on Sep. 8, 2008.

(30) Foreign Application Priority Data
Sep. 7, 2007 (JP) 2007-233138

(51) Int. Cl. H01L 33/00

(52) U.S. Cl. 257/98; 438/29; 257/E33.067; 257/E33.056

(57) ABSTRACT

There is provided a glass-covered light-emitting element and a glass-covered light-emitting device, which contain a properly low content of bubbles that reduce transmittance by scattering of visible light, and which are covered with a glass film having a total light transmittance of 85% or more

The glass-covered light-emitting element is covered with glass, which is formed of calcined glass frit, which has a softening temperature of 600° C. or less, which has a total light transmittance of 85% or more, which a coefficient of thermal expansion of 70×10⁻⁷/° C. to 125×10⁻⁷/° C., and which has a content of bubbles having a diameter of 1 μm or more, the content being 500,000 bubbles/mm³ or less.

### BACKGROUND OF THE INVENTION

1. Field of the Invention

The present invention relates to a glass-covered light-emitting element and a glass-covered light-emitting device, which are covered with glass, in particular a glass covering-material.

2. Discussion of Background

In recent years, it has been proposed to employ glass as a material for covering a semiconductor light-emitting element (such as a light-emitting diode). It has been disclosed that glass employed as such a covering material is prepared by calcining glass powder (glass frit) (see Patent Document 1).

Patent Document 1: JP-A-2007-182529

### SUMMARY OF THE INVENTION

In general, particles having substantially the same size as the wavelength of light cause Mie scattering to disturb the transmittance of the light. The presence of such particles also causes a critical problem, such as a reduction in transmittance, for a covering material, such as glass or a resin, for effectively transmitting light emitted from a light-emitting element. The reason is that bubbles exist in such a covering material (in particular glass) for covering a light-emitting element.

However, Patent Document 1 is almost silent on the problem of disturbing transmittance by bubbles. The solution proposed by this reference is supposed to involve a problem of failure in having a desired luminous efficiency.

It is an object of the present invention to provide a glass covering-material, which efficiently transmits light emitted from a light-emitting element, and a light-emitting element covered with such a glass covering-material.

### BRIEF DESCRIPTION OF THE DRAWINGS

Specifically, the present invention is proposed as follows:

1) The glass-covered light-emitting element according to the present invention is characterized to be covered with glass, the glass being formed of calcined glass frit, and the glass having a content of bubbles having a diameter of 1 μm or more, the content being 500,000 bubbles/mm³ or less.

2) In the glass-covered light-emitting element according to the present invention, it is preferred that the glass have a content of bubbles having a diameter of 3 μm or more, the content being 25,000 bubbles/mm³ or less.

3) In the glass-covered light-emitting element according to the present invention, it is preferred that the glass have a softening temperature of 600° C. or less.

4) In the glass-covered light-emitting element according to the present invention, it is preferred that the glass have a total light transmittance of 85% or more.

5) In the glass-covered light-emitting element according to the present invention, it is preferred that the glass have a coefficient of thermal expansion of 70×10⁻⁷/° C. to 125×10⁻⁷/° C.

6) In the glass-covered light-emitting element according to the present invention, it is preferred that the glass be glass selected from the group consisting of TeO₂—ZnO based glass, B₂O₃—Bi₂O₃ based glass, SiO₂—Bi₂O₃ based glass, SiO₂—ZnO based glass, B₂O₃—ZnO based glass, P₂O₅—ZnO based glass and P₂O₅—SnO based glass, or composite glass containing at least two kinds selected from the above-mentioned group.

7) The glass-covered light-emitting device according to the present invention is characterized to include a substrate; a glass-covered light-emitting element defined in any one of items 1) to 6), the glass-covered light-emitting element being a semiconductor light-emitting element mounted on the substrate, the semiconductor light-emitting element being covered with glass; and the glass covering a front side and a lateral side of the semiconductor light-emitting element to integrate the semiconductor light-emitting element with the substrate.

8) The process for fabricating a glass-covered light-emitting element according to the present invention is characterized that in a process for fabricating a glass-covered light-emitting element defined in any one of items 1) to 6), including covering a semiconductor light-emitting element with glass frit; heating the glass frit to soften and fluidize the glass frit so as to cover the semiconductor light-emitting element with the glass, further including conducting reduced-pressure treatment when heating the glass frit.

9) The process for fabricating a glass-covered light-emitting device according to the present invention is characterized in that in a process for fabricating a glass-covered light-emitting device defined in item 7, the process includes covering, with glass frit, a semiconductor light-emitting element mounted on a substrate; heating the glass frit to soften and fluidize the glass frit so as to cover the semiconductor light-emitting element with the glass, further comprising conducting heating the glass frit before covering the semiconductor light-emitting element with the glass frit; followed by covering the semiconductor light-emitting element with the glass frit, and conducting reduced-pressure treatment when heating the glass frit for calcination.

In accordance with the present invention, it is possible to provide a glass-covered light-emitting element and a glass-covered light-emitting device, which contain a properly low content of bubbles having a diameter of 1 μm or more that reduce transmittance by scattering of visible light, which are covered with a glass film having a total light transmittance of 85% or more, and which are useful as a backlight light source for a liquid crystal panel.

### BRIEF DESCRIPTION OF THE DRAWINGS

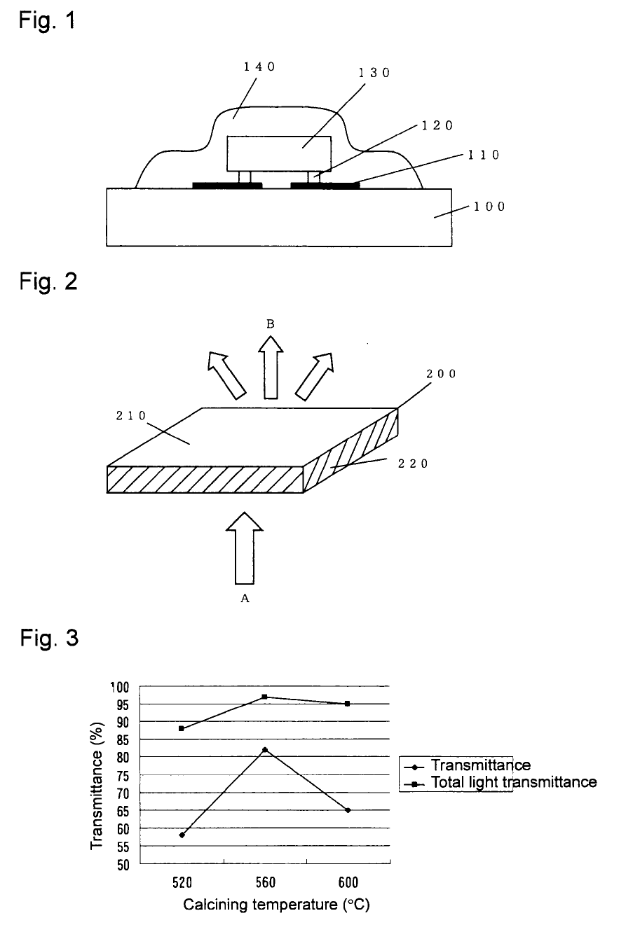

FIG. 1 is a cross-sectional view of the glass-covered light-emitting device according to an embodiment of the present invention;

FIG. 2 is a schematic view showing how to measure the number of bubbles in and optical characteristics of the glass according to the present invention; and

FIG. 3 is a graph showing transmittance and total light transmittance in the present invention.

### DETAILED DESCRIPTION OF THE PREFERRED EMBODIMENTS

The glass-covered light-emitting element according to the present invention may be a semiconductor light-emitting element, such as a light-emitting diode, covered with glass. In a simple structure, the semiconductor light-emitting element may be mounted on leading ends of two metal wires and have its entire periphery covered with glass. The semiconductor light-emitting element may be mounted on a substrate so as to be integrated with the substrate by glass, thus providing a glass-covered light-emitting device. In both cases, a covering layer, which is made of glass, is disposed on a side from which light is emitted.

Embodiments of the present invention will be described in detail below, referring the accompanying drawings. In the drawings, like reference numerals indicate corresponding parts. The following embodiments are exemplary only. Changes and/or modifications may be made within the concept and the scope of the present invention.

Firstly, the glass-covered light-emitting device will be described in reference to an accompanying drawing.

FIG. 1 is a cross-sectional view of the glass-covered light-emitting device according to an embodiment of the present invention. The glass-covered light-emitting device according to this embodiment includes a substrate 100, wiring 110 disposed on the substrate, bumps 120 electrically connected to the wiring 110, a semiconductor light-emitting element 130 electrically connected to the wiring 110 through the bumps 120, and glass 140 as a covering material for covering the semiconductor light-emitting element 130.

The substrate may be an alumina substrate, a sapphire substrate or a magnesia (MgO) substrate, which has a purity of 98.0% to 99.5%, a thickness of 0.5 mm to 1.2 mm and a rectangular shape, for example. The wiring disposed on the substrate 100 may be gold wiring prepared from gold paste.

The semiconductor light-emitting element 130 includes a substrate, an LED, a positive electrode and a negative electrode. The LED may be an LED (InGaN-based LED), which emits ultraviolet light or blue light having a wavelength of 360 nm to 480 nm and has a quantum well structure having a light-emitting layer formed of InGaN with In added to GaN, for example. The substrate of the semiconductor light-emitting element has a coefficient of thermal expansion (α) of 70×10⁻⁷/° C. to 90×10⁻⁷/° C.

A sapphire substrate, which has a coefficient of thermal expansion of about 80×10⁻⁷/° C., is normally employed as the substrate.

Next, the glass employed for covering the light-emitting element according to the present invention will be described.

The glass employed for the glass-covered light-emitting element and the glass-covered light-emitting device according to the present invention is prepared by calcining glass frit. Among the bubbles contained in the glass, the content of bubbles having a diameter of 1 μm or more is 500,000 bubbles/mm³ or less. Thus, the glass has an increased light transmission amount, obtaining an increased effective illumination. When the number of bubbles having a diameter of 1 μm or more is beyond 500,000 bubbles/mm³, it is unlikely that the total light transmittance meets 80%.

Since bubbles having a larger diameter have a greater adverse effect, the content of bubbles having a diameter of 2 μm or more in the glass is preferably 100,000 bubbles/mm³ or less, more preferably 60,000 bubbles/mm³ or less. Further, the content of bubbles having a diameter of 3 μm or more in the glass is preferably 25,000 bubbles/mm³ or less, more preferably 15,000 bubbles/mm³ or less. Furthermore, the content of bubbles having a diameter of 4 μm or more in the glass is preferably 5,000 bubbles/mm³ or less, more preferably 3,000 bubbles/mm³ or less. In particular, the content of bubbles having a diameter of 5 μm or more is preferably zero.

When the number of bubbles having a diameter of 1 μm or more occupies 100% of the total number of the bubbles, the number of bubbles having a diameter of 2 μm or more is preferably 20% or less of the total number of the bubbles. Further, the number of bubbles having a diameter of 3 μm or more is preferably 5% or less of the total number of the bubbles. Furthermore, the number of bubbles having a diameter of 4 μm or more is preferably 1% or less of the total number of the bubbles. In particular, the number of bubbles having a diameter of 5 μm or more is preferably zero.

Particularly, the content of bubbles having a diameter of 3 μm or more has a volume fraction of preferably 0.01 vol % or less.

The content of bubbles having a diameter of 1 μm or more is preferably 300,000 bubbles/mm³ or less, more preferably 200,000 bubbles/mm³ or less, most preferably 150,000 bubbles/mm³ or less.

The glass for covering the light-emitting element according to the present invention has a glass transition temperature (Tg) of preferably 500° C. or less, more preferably 490° C. or less, most preferably 480° C. or less. The glass transition temperature has a lower limit of 150° C. When the glass transition temperature (Tg) is beyond 500° C., it is likely that an LED element is degraded by an increase in the sealing temperature for the LED element.

The glass for covering the light-emitting element according to the present invention has a glass softening temperature (Ts) of preferably 600° C. or less, more preferably 590° C. or less, most preferably 580° C. or less. The glass softening temperature has a lower limit of 300° C. When the glass softening temperature (Ts) is beyond 600° C., it is likely that an LED element is degraded by an increase in the sealing temperature for the LED element.

The glass for covering the light-emitting element according to the present invention has a coefficient of thermal expansion (a) of 125×10⁻⁷/° C. or less, more preferably 95×10⁻⁷/° C. or less, most preferably 90×10⁻⁷/° C. or less. When the coefficient of thermal expansion (a) is less than 70×10⁻⁷/° C., the glass transition temperature increases. The coefficient of thermal expansion is preferably 70×10⁻⁷/° C. or more, more preferably 75×10⁻⁷/° C. or more, most preferably 80×10⁻⁷/° C. or more. When the coefficient of thermal expansion (α) is beyond 125×10⁻⁷/° C., there are e.g. problems in that in a process for softening glass to seal a semiconductor light-emitting element and cooling the sealed semiconductor light-emitting element to room temperature, or in a subsequent process, a crack occurs, starting at a portion of the glass in contact with the semiconductor light-emitting element, to lower a light take-out efficiency, or to expose the semiconductor light-emitting element to atmospheric moisture.

The glass for covering the light-emitting element according to the present invention may be glass selected in the group consisting of TeO₂—ZnO based glass, B₂O₃—Bi₂O₃ based glass, SiO₂—Bi₂O₃ based glass, SiO₂—ZnO based glass, B₂O₃—ZnO based glass, P₂O₅—ZnO based glass and P₂O₅—SnO based glass, or composite glass containing at least two kinds selected from the above-mentioned glass.

In the process for fabricating the glass-covered light-emitting element according to the present invention, a semiconductor light-emitting element is covered with glass frit, and the glass frit is heated and is calcined to be softened and fluidized, thereby covering the semiconductor light-emitting element with the glass. It is possible to decrease the number of the bubbles in the glass by conducting reduced-pressure treatment during heating the glass frit. The reduced-pressure treatment during heating the glass frit may be conducted in the entire heating step or in part of the heating step as long as the number of the bubbles falls within the above-mentioned ranges.

In the process for fabricating the glass-covered light-emitting device according to the present invention, a semiconductor light-emitting element mounted on a substrate is covered with glass frit, and the glass frit is heated and is calcined to be softened and fluidized, thereby covering the semiconductor light-emitting element with the glass. In this case, it is preferred that such a substrate be first heated to remove organic substances as contaminations adhering to the surface thereof before covering such a semiconductor light-emitting element with glass frit. After that, it is preferred that the semiconductor light-emitting element be mounted on the substrate and be covered with glass frit, and such reduced-pressure treatment be conducted during heating the glass frit for calcination, thereby decreasing the number of the bubble in the glass.

The pressure in the above-mentioned reduced-pressure treatment may be selected in a range of about 50 kPa to 0.5 Pa, preferably about 10 kPa to 1 Pa, depending on the glass composition, the heating temperature, the thickness or another factor of employed glass, such that the number of the bubbles falls within the range according to the present invention.

The glass-covered light-emitting element and the glass-covered light-emitting device obtained by the present invention are applicable as a backlight source for a liquid crystal panel, general illumination, a headlight for an automobile, and the like, which employ a glass-covered LED element as a light-emitting element.

### Example

Now, the present invention will be described in more detail in reference to examples. The present invention should not be construed as being limited to the examples.

### <Fabrication of Covering-Glass>

Two kinds of B₂O₃—ZnO based glass having different contents in a composition constituting glass were employed. In order to obtain the glass in each of Examples 1 and 2, paste was prepared by mixing and kneading glass powder (75 parts by mass) having a composition identified in the following Table 1 and a vehicle (25 parts by mass) described below. Each covering glass was obtained in bulk by applying such paste, followed by calcination.

The vehicle was a mixture of a resin, a solvent and a surfactant and in Examples, prepared by blending butyl-di-gycol-acetate (manufactured by DAICEL CHEMICAL INDUSTRIES LTD.), α-terpineol (manufactured by YASUHARA CHEMICAL CO., LTD.) and ethyl cellulose (manufactured by the Dow Chemical Company) with a ratio of 6:3:1 by mass %. The glass shown in Table 1 was not prepared so as to contain only the components listed in Table 1 but was prepared to contain BaO, Li₂O and the like in addition.

With respect to the glass obtained in each of Examples 1 and 2, the glass transition temperature Tg (unit: ° C.), the glass softening temperature Ts (unit: ° C.) and the coefficient of thermal expansion a (unit: 10⁻⁷/° C.) were measured as the following method.

Glass transition temperature (Tg): Each sample of 250 mg, which was powdered, was filled in a platinum pan and was measured at a rate of temperature increase of 10° C./minute by a differential thermal analyzer (product name of Thermo Plus TG8110) manufactured by Rigaku Corporation.

Glass softening temperature (Ts): Each sample of 250 mg, which was powered, was filled in the platinum pan and measured at a rate of temperature increase of 10° C./minute by the differential thermal analyzer (product name of Thermo Plus TG8110) manufactured by Rigaku Corporation.

Coefficient of thermal expansion (α): Each sample, which was prepared in a column shape having a diameter of 5 mm and a length of 20 mm, was measured at a rate of temperature increase of 10° C./minute by a thermal dilatometer (horizontal differential detection type of thermal dilatometer TD5010 manufactured by Bruker AXS K.K.). The coefficients of expansion from 25° C. to 250° C. were found at every 25° C., and the average value of the found coefficients was showed as α.

The measurement results are shown in Table 1.

TABLE 1

| | Example 1 (mol %) | Example 2 (mol %) |
|---|---|---|
| SiO₂ | 15 | 18 |
| B₂O₃ | 30 | 32 |
| ZnO | 25 | 21 |
| Tg (° C.) | 472 | 483 |
| Ts (° C.) | 579 | 583 |
| α (×10⁻⁷/° C.) | 79 | 78 |

### <Fabrication of Glass-Covered Light-Emitting Element)

Next, magnesia substrates with a gold wiring pattern disposed thereon (having a thickness of 1 mm and dimensions of 7 mm×5 mm), and LEDs manufactured by Toyoda Gosei Co., Ltd. (product name of E1C60-0B011-03) and having connection bumps disposed thereon were prepared, and each LED was mounted on each magnesia substrate by flip chip bonding. After that, in order to refrain bubbles from generating at the interface of glass and a substrate, each magnesia substrate with an LED mounted thereon was put into an electrical furnace (IR heating system) to be heated at 600° C. The rate of temperature increase, the holding time at 600° C. and the rate of temperature decrease were set at 300° C./minute, 2 minutes and 300° C./minute, respectively. The bubbles that generate at the intersurface between glass and a substrate are generated as glass reacts in response to organic contaminants adhering to a substrate surface when the glass is softened. Since the generated bubbles refract light emitted from a semiconductor light-emitting element, it is likely that the luminance of the light-emitting device reduced or that the light distribution of the light-emitting device is changed. For these reasons, the organic contaminants adhering to the substrate surface were decreased to refrain bubbles from being generated by heating each substrate with an LED mounted thereon before covering the LED with glass.

The inventors have already found that the heating temperature is preferably around 600° C., and that the heating period is preferably around 2 minutes in consideration of thermal effect on LEDs. The LEDs were mounted on the chips under the above-mentioned conditions.

A spatula was used to drip (print) a slight amount of the above-mentioned paste on each of the flip-chip mounted LEDs and is dried once, then the spatula was also used to drip a slight amount of the paste on each of the LEDs again to reshape the LEDs. After that, each of the LEDs was put into the electrical furnace to be heated up to 450° C. at a rate of temperature increase of 10° C./minute and was maintained at 450° C. for 20 minutes, thereby burning out binder components as organic substances (such as the vehicle). While each of the LEDs was maintained at 450° C., reduced-pressure treatment (10 Pa) was conducted by vacuating the inside of the electrical furnace. After that, the heating temperature was raised to 580° C. at a rate of temperature increase of 10° C./minute with the reduced-pressure state maintained, and the heating temperature was kept at 580° C. for 30 minutes. While the heating temperature was kept at 580° C., the electric furnace was put in the vacuated state to maintain the reduced-pressure treatment. In this way, the glass was softened and fluidized to cover each LED. Then, the heating temperature was reduced at rate of temperature decrease of 10° C./minute to cool each LED.

Each glass covering each LED was visually observed, which showed that there were no bubbles in the vicinity of the surface of each glass.

When a DC voltage was applied across each glass-covered light-emitting element thus obtained, it was verified that blue light was emitted. As shown in Table 2, no significant difference between both Examples about current-voltage measurements before and after sealing (the value of a voltage when 10 mA of current flowed). This revealed that there were no damage in the light-emitting layer of each LED element.

TABLE 2

| | | | Difference |
|---|---|---|---|
| | Voltage before | Voltage after | between before |
| | sealing (V) | sealing (V) | and after (V) |
| Example 1 | 2.85 | 2.98 | 0.13 |
| Example 2 | 2.87 | 2.91 | 0.04 |

### <Measurement of the Number of Bubbles and Optical Characteristics)

Now, the glass-covered light emitting element according to the present invention will be more specifically described in terms of the number of bubbles and optical characteristics. In order to simplify the measurements of the number of bubbles and the optical characteristics in the examples, samples shown in FIG. 2 were fabricated to investigate the number of bubbles and the optical characteristics (total light transmittance and haze) in the glass covering each light emitting element. The wording “total light transmittance” means the transmittance of a light beam formed of a combination of linear (non-scattered) transmitted light and backward scattering light.

Each sample shown in FIG. 2 was formed of a rectangular glass substrate 200 (a glass substrate manufactured by Asahi Glass Company, Limited, having a product name of PD200 and dimensions (length×width×thickness) of 200 mm×200 mm×1 mm). The glass film 210 of each of Examples 1 and 2 was applied on each substrate. The calcining temperature and the reduced-pressure condition were set at the same conditions as the process for covering the above-mentioned LEDs. Another glass substrate was employed to prepare a sample as a Comparative Example at the same calcining temperature without being subjected to reduced-pressure. In the measurement, a light beam A was applied to the rear side of each glass substrate 200 without the glass film 210 being disposed, and an integrated sphere was employed to collect all light beams that passed through the glass substrate 200 and its glass film 210 and came out of the glass film 210. The four lateral sides 220 of each glass substrate 200 were painted out in black. Since the four lateral sides were painted out in black, the light emitted from the lateral sides 220 of each glass substrate 200 was prevented from coming into the integrating sphere. The total light transmittance of the samples was standardized such that each glass substrate 200 had a total transmitted light intensity of 100% when having no glass film 210 disposed thereon.

Tables 3 and 4 show the measurement results that revealed how the number of bubbles, the total light transmittance and the haze were affected by the presence and absence of the reduced-pressure treatment with respect to a sample (a sample with the glass film of Example 1 disposed thereon) fabricated in accordance with the glass-covering process of the present invention with the reduced-pressure step included therein (hereinbelow, referred to as the process according to the present invention) and a sample that employed the glass of Example 1 and was fabricated in accordance with a conventional glass-covering process (hereinbelow, referred to as the conventional process).

In Table 3, the number of bubbles (total number) represents the number of bubbles having a diameter of 0.6 μm or more in a portion of 110 μm×110 μm×100 μm. The total light transmittance Tₜ (unit: %) and the haze Tₕ (unit: %) were measured by the following measuring methods.

Total light transmittance Tₜ: The measurements were conducted by an integrating sphere measuring device for light transmittance (manufactured by Suga Test Instruments Co., Ltd., Product Name: Direct-reading haze computer), and the ratio (T₂/T₁) of the total quantity of light passing through the sample (T₂) to the quantity of incident visible light (T₁) with respect to each sample is expressed in percentage.

Haze (Tₕ): The light transmittance of each sample was measured in the same way as the measurements for total light transmittance, and the values were found by the formula of Tₕ=T_{d}/Tₜ. The value of T_{d} represents the transmittance of scattering light.

TABLE 3

| | Without reduced- | With reduced- |
|---|---|---|
| | pressure | pressure |
| Number of bubbles | 1633 | 307 |
| (total amount) | | |
| Number of bubbles | 1166 | 149 |
| having a diameter of | | |
| 1 μm or more | | |
| Number of bubbles | 229 | 20 |
| having a diameter of | | |
| 2 μm or more | | |
| Number of bubbles | 38 | 2 |
| having a diameter of | | |
| 3 μm or more | | |
| Number of bubbles | 7 | 0 |
| having a diameter of | | |
| 4 μm or more | | |
| Number of bubbles | 0 | 0 |
| having a diameter of | | |
| 5 μm or more | | |

TABLE 4

| | Without reduced- | With reduced- |
|---|---|---|
| | pressure | pressure |
| Total light | 79 | 90.2 |
| transmittance (%) | | |
| Haze (%) | 41.4 | 14.6 |

As seen from Table 3, the total number of the bubbles in the sample fabricated by the process according to the present invention (the sample employing the glass film of Example 1) was one-fourth or less the total number of the bubbles in the sample fabricated by the conventional process. A comparison of the number of bubbles having a diameter of 2 μm or more indicated that the number of bubbles in the sample fabricated by the process according to the present invention was 20 while the number of bubbles in the sample according to the conventional process was 229, which means that the number of bubbles in the sample fabricated by the process according to the present invention was less than one-tenth. In particular, a comparison of the number of bubbles having a diameter of 1 μm or more, which is supposed to affect the total light transmittance, indicated that the number of bubbles in the sample fabricated by the process according to the present invention was 149 while the number of bubbles in the sample according to the conventional process was 1,166, which means that the reduced-pressure treatment led to a significant reduction in the number of bubbles having a diameter of 1 μm or more.

The measurement of the optical characteristics revealed as seen from Table 4 that the total light transmittance and the haze of the sample fabricated by the process according to the present invention were both significantly improved in comparison with those of the sample according to the conventional process.

The numbers of bubbles in Table 3 show the numbers of bubbles existing in a portion of 110 μm×110 μm×100 μm. The calculation results that are obtained by converting the shown numbers to numbers per unit volume (1 mm³) are shown in Table 5. The conversion to the unit volume was made according to the formula of Y=X/(0.11×0.11×0.1), where X represented the number of bubbles existing in a portion of 110 μm×110 μm×100 μm. The volume fraction of bubbles having a diameter of 3 μm or more was 0.0037 vol % for the process with reduced-pressure and 0.085 vol % for the process without reduced-pressure.

TABLE 5

| | Without reduced- | With reduced- |
|---|---|---|
| | pressure | pressure |
| Number of bubbles | 1,349,587 | 253,719 |
| (total amount) | | |
| Number of bubbles | 963,636 | 123,140 |
| having a diameter of | | |
| 1 μm or more | | |
| Number of bubbles | 189,256 | 16,529 |
| having a diameter of | | |
| 2 μm or more | | |
| Number of bubbles | 31,405 | 1,653 |
| having a diameter of | | |
| 3 μm or more | | |
| Number of bubbles | 5,785 | 0 |
| having a diameter of | | |
| 4 μm or more | | |
| Number of bubbles | 0 | 0 |
| having a diameter of | | |
| 5 μm or more | | |

As seen from Table 5, it was found that the number of bubbles having a diameter of 1 μm or more and the number of bubbles having a diameter of 2 μm or more were 123,140 (for the treatment with reduced-pressure) and 16,529 (for the treatment with reduced-pressure), respectively in the unit volume of 1 mm³. This reveals that it is preferred that the number of bubbles having a diameter of 1 μm or more be 500,000 or less in the unit volume of 1 mm³. When the number of such bubbles is beyond 500,000, it is likely that the total light transmission fails to achieve 80%.

It should be noted that the inventors do not recognize that a reduction in the number of only bubbles a diameter of 1 μm or more is helpful to improve the transmittance. For example, as described about the object solved by the present invention, a reduction in transmittance is caused by the existence of bubbles having a diameter substantially equal to the wavelength of transmitted light, and it is preferred to reduce the number of bubbles having a diameter substantially equal to the wavelength. In this regard, the inventors have considered that the diameter of bubbles that reduce transmittance because of MIE scattering is 0.1 μm to 1 μm for a glass film covering a light emitting element.

On the other hand, the inventors have thought that a reduction in the number of bubbles having a diameter of 1 μm or more is also helpful to reduce the number of bubbles having a diameter of 0.1 μm to 1 μm, which introduces the phenomenon of the MIE scattering. In other words, the inventors have considered that the treatment for reducing the number of bubbles having a diameter of 1 μm or more has led to a reduction in the number of bubbles having a diameter of 0.1 μm to 1 μm. It is supposed that bubbles having a diameter of less than 0.1 μm have little effect on a reduction in transmittance because of having a small volume fraction.

### <Measurement of External Quantum Efficiency of Glass-Covered Light Emitting Element>

The external quantum efficiency (unit: %) with respect to each of the glass-covered light-emitting elements in samples, which were obtained by employing the glass described above (though only Sample 5 was a comparative example without having glass covering), as measured. The measurement results were obtained as shown in Table 6. The wording of “external quantum efficiency” means to show how many particles of light come out of an LED when one electron and one hole combine. For example, in a case where one hundred electrons and one hundred holes combine, when twenty particles of light come out, the external quantum efficiency was set at 20%. In the measurements, the external quantum efficiency represents the number of particles of light passing through each glass and coming out of each glass since each light-emitting element was entirely covered with each glass.

As shown in Table 6, the bare light-emitting element without having a glass-covering had an external quantum efficiency of 16.8. It was revealed that the light-emitting elements having conventional glass-coverings different from the glass-covering according to the present invention had an external quantum efficiency of 14.3 to 16.5, which was inferior to the external quantum efficiency of the bare light-emitting element.

On the other hand, it was revealed that the light-emitting elements fabricated by the process according to the present invention had an external quantum efficiency of 21.3 to 21.5, which was improved by 1.3 times in comparison with the external quantum efficiency of the bare light-emitting element.

These results show that the glass-covered light-emitting element according to the present invention has a higher luminous efficiency.

With regard to the thickness of glass listed in Table 6, the wording of “small” means that each of the covering layers has a thickness of about 100 μm, and the wording of “large” means that each of the covering layers has a thickness of about 200 μm

TABLE 6

| | | Process | | |
|---|---|---|---|---|
| | Presence | according to | | External |
| | and absence | the present | Thickness | quantum |
| Sample | of glass | invention | of glass | efficiency (%) |
| 1 | Present | Applied | Small | 21.3 |
| 2 | Present | Applied | Large | 21.5 |
| 3 | Present | Not applied | Small | 14.3 |
| 4 | Present | Not applied | Large | 16.5 |
| 5 | Absent | — | — | 16.8 |

FIG. 3 is a graph showing the non-scattered transmittance and the total light transmittance of the glass-covered light emitting element according to the present invention. As shown in FIG. 3, the glass-covered light emitting element according to the present invention has a transmittance of higher than 85% when the calcining temperature was set at a temperature of 520° C. to 600° C. When the calcining temperature is set at 560° C., the glass-covered light emitting element according to the present invention has a total light transmittance of higher than 95%.

### INDUSTRIAL APPLICABILITY

The glass-covered light emitting element according to the present invention are industrially useful as a backlight light source for a liquid crystal panel, general illumination, a headlight for an automobile, and the like because of having a significantly high light transmittance.

The entire disclosure of Japanese Patent Application No. 2007-233138 filed on Sep. 7, 2007 including specification, claims, drawings and summary is incorporated herein by reference in its entirety.

What is claimed is:

1. A glass-covered light-emitting element comprising a semiconductor light-emitting element covered with glass, the glass comprising calcined glass frit, and the glass having a content of bubbles having a diameter of 1 μm or more, the content being 500,000 bubbles/mm³ or less.

2. The glass-covered light-emitting element according to claim 1, wherein the glass has a content of bubbles having a diameter of 3 μm or more, the content being 25,000 bubbles/mm³ or less.

3. The glass-covered light-emitting element according to claim 1, wherein the glass has a softening temperature of 600° C. or less.

4. The glass-covered light-emitting element according to claim 1, wherein the glass has a total light transmittance of 85% or more.

5. The glass-covered light-emitting element according to claim 1, wherein the glass has a coefficient of thermal expansion of 70×10⁻⁷/° C. to 125×10⁻⁷/° C.

6. The glass-covered light-emitting element according to claim 1, wherein the glass comprises glass selected from the group consisting of TeO₂—ZnO based glass, B₂O₃—Bi₂O₃ based glass, SiO₂—Bi₂O₃ based glass, SiO₂—ZnO based glass, B₂O₃—ZnO based glass, P₂O₅—ZnO based glass and P₂O₅—SnO based glass, or composite glass containing at least two kinds selected from said group.

7. A glass-covered light-emitting device comprising:
a substrate;
a glass-covered light-emitting element defined in claim 1, the glass-covered light-emitting element comprising a semiconductor light-emitting element mounted on the substrate, the semiconductor light-emitting element being covered with glass; and
the glass covering a front side and a lateral side of the semiconductor light-emitting element to integrate the semiconductor light-emitting element with the substrate.

8. A process for fabricating a glass-covered light-emitting element defined in claim 1, comprising covering a semiconductor light-emitting element with glass frit; heating the glass frit to soften and fluidize the glass frit so as to cover the semiconductor light-emitting element with the glass, further comprising conducting reduced-pressure treatment when heating the glass frit.

9. A process for fabricating a glass-covered light-emitting device defined in claim 7, comprising covering, with glass frit, a semiconductor light-emitting element mounted on a substrate; heating the glass frit to soften and fluidize the glass frit so as to cover the semiconductor light-emitting element with the glass, further comprising conducting heating the glass frit before covering the semiconductor light-emitting element with the glass frit; followed by covering the semiconductor light-emitting element with the glass frit, and conducting reduced-pressure treatment when heating the glass frit for calcination.
